(19) United States
(12) Patent Application Publication
(10) Pub. No.: US 2012/0279563 A1
(43) Pub. Date: Nov. 8, 2012

(54) SOLDERABLE INTERCONNECT APPARATUS FOR INTERCONNECTING SOLAR CELLS

(76) Inventors: Daniel Meier, Norcross, GA (US); Vijay Yelundur, Canton, GA (US); Vinodh Chandrasekaran, Suwanee, GA (US); Adam M. Payne, Dunwoody, GA (US); Sheri X. Wang, Duluth, GA (US)

(21) Appl. No.: 13/098,817

(22) Filed: May 2, 2011

(51) Int. Cl. H01L 31/0224; B23K 1/20; H01L 31/18

(52) U.S. Cl. 136/256; 438/98; 228/256; 257/E31.124

(57) ABSTRACT

Interconnect apparatus and methods for their manufacture are disclosed. An example method for forming a solderable connection to a conductive surface may include forming one or more solderable metal regions on the conductive surface, for example an aluminum surface. The method may comprise applying a solder layer to the one or more solderable metal regions to form one or more soldered metal regions. The method may further comprise depositing one or more solderable metal regions on the conductive surface by plasma deposition. In other examples, the one or more solderable metal regions may be sputtered. Additionally, the method may comprise applying a flux to the one or more solderable metal regions prior to applying the solder layer to the one or more solderable metal regions. An interconnect ribbon may be soldered to at least one of the solder layer or the solderable metal regions. Associated interconnect apparatus are also provided.

### TECHNOLOGICAL FIELD

Embodiments of the present invention relate generally to apparatus and methods for interconnecting solar cells. More particularly, embodiments of the present invention are directed to a solderable interconnect apparatus for interconnecting solar cells, and methods for its manufacture.

### BACKGROUND

In basic design, a solar cell is composed of a material such as a semiconductor substrate that absorbs energy from photons to generate electricity through the photovoltaic effect. When photons of light penetrate into the substrate, the energy is absorbed and an electron previously in a bound state is freed. The released electron and the previously occupied hole are known as charge carriers.

The substrate is generally doped with p-type and n-type impurities to create an electrical field inside the solar cell at a p-n junction. In order to use the free charge carriers to generate electricity, the electrons and holes must not recombine before they can be separated by the electrical field at a p-n junction. The electrons will then be collected by the electrical contacts on the n-type layer and the holes will be collected by the electrical contacts on the p-type layer. The charge carriers that do not recombine are available to power a load.

A common method for producing solar cells begins with a substrate doped to have p-type or n-type conductivity, which may be referred to as p-type solar cells or n-type solar cells, respectively. A dopant of the opposite conductivity is introduced to the front or back surface of the substrate to form an emitter layer on the top or bottom of a base layer. Typically, the substrate is moderately doped with dopant of a first conductivity, while the emitter layer is heavily doped with dopant of a second conductivity type. As a result of forming the emitter layer, a p-n junction is formed at the interface of the emitter layer and the base layer. Contacts are then formed on the emitter layer and the base layer to allow electrical connections to be made to the solar cell.

Solar cells are commonly connected together in groups to produce a solar module. A typical approach involves connecting a contact of a first solar cell to a contact of a second solar cell using an interconnecting medium. Various interconnecting mediums, however, may have difficulty connecting to certain types of contact materials, such as materials that are not solderable. For example, connections to some contact materials may not be sufficiently durable or reliable, or may not be possible by soldering. Additionally, connections to some contact materials may negatively affect the efficiency and operation of the solar cells being connected.

Therefore, there is a need in the art for materials and methods for interconnecting solar cells that overcome the above-mentioned and other disadvantages and deficiencies of previous technologies.

### BRIEF SUMMARY OF SOME EXAMPLES OF THE INVENTION

Various embodiments of a solderable interconnect apparatus are described herein. More particularly, an interconnect apparatus comprising a soldered, copper layer may be formed to a solar cell having a full aluminum back contact to allow the solar cell to be interconnected with adjacent solar cells, for example in a solar module. These embodiments of the invention overcome one or more of the above-described disadvantages associated with previous technologies.

Embodiments of the invention provide several advantages for forming an interconnect apparatus on non-solderable surfaces. According to an example embodiment of the invention, a method is disclosed for forming a rear junction solar cell having a solderable connection. The method may comprise fabricating an n-type base layer. Furthermore, the method may comprise applying a contact layer to one side of the n-type base layer. The method may further comprise alloying the contact layer with at least a portion of the n-type base layer thereby forming a p-type emitter layer such that the n-type base layer overlies the p-type emitter layer; a contact such that the p-type emitter layer overlies the contact; and a p-n junction at the interface of the n-type base layer and the p-type emitter layer. The method may further comprise forming one or more solderable metal regions on the contact. Additionally, the method may comprise applying a solder layer to the one or more solderable metal regions to form one or more soldered metal regions. The solder layer may comprise about sixty percent tin and about forty percent lead. Moreover, the one or more solderable metal regions may comprise one or more copper soldering pads. The method may further comprise depositing the one or more copper soldering pads on the contact by plasma deposition. The method may further comprise soldering an interconnect ribbon to at least one of the solder layers or the one or more solderable metal regions.

According to another example embodiment of the invention, a rear junction solar cell having a solderable connection is disclosed. The solar cell may comprise a substrate comprising an n-type base layer. Furthermore, the solar cell may comprise a p-type emitter layer. The n-type base layer may overlie the p-type emitter layer. The solar cell may further comprise a p-n junction at the interface of the n-type base layer and the p-type emitter layer. Moreover, the solar cell may comprise a contact. The p-type emitter layer may overlie the contact. The solar cell may further comprise one or more solderable metal regions formed on the contact. Furthermore, the solar cell may comprise a solder layer formed on the one or more solderable metal regions thereby forming one or more soldered metal regions.

According to another example embodiment of the invention, a method is disclosed for forming a solderable connection to a conductive surface. The method may comprise forming one or more solderable metal regions on the conductive surface. Furthermore, the method may comprise applying a solder layer to the one or more solderable metal regions to form one or more soldered metal regions.

According to an example embodiment of the invention, an interconnect apparatus is disclosed for forming a solderable connection to a conductive surface. The interconnect apparatus may further comprise one or more solderable metal regions formed on the conductive surface. Moreover, the interconnect apparatus may comprise a solder layer formed on the one or more solderable metal regions thereby forming one or more soldered metal regions.

According to another example embodiment of the present invention, a solar cell having a solderable connection is disclosed. The solar cell may comprise a back contact. Furthermore, the solar cell may comprise one or more solderable metal regions formed on the back contact. The solar cell may also comprise a solder layer formed on the one or more solderable metal regions thereby forming one or more soldered metal regions. Additionally, the solar cell may comprise a substrate comprising a p-type base layer. The solar cell may further comprise an n-type emitter layer formed over the p-type base layer. Furthermore the solar cell may comprise a p-n junction at the interface of the p-type base layer and the n-type emitter layer. The back contact may be formed on the back surface of the p-type base layer.

According to an additional example embodiment of the present invention, a method is disclosed for forming a solar cell having a solderable connection. The method may comprise fabricating a p-type base layer. Additionally, the method may comprise forming an n-type emitter layer overlying the p-type base layer, thereby forming a p-n junction at the interface of the p-type base layer and the n-type emitter layer. The method may further comprise forming a contact on a surface of the p-type base layer opposite the n-type emitter layer. Moreover, the method may comprise forming one or more solderable metal regions on the contact. The method may additionally comprise applying a solder layer to the one or more solderable metal regions thereby forming one or more soldered metal regions.

The above summary is provided merely for purposes of summarizing some example embodiments of the invention so as to provide a basic understanding of some aspects of the invention. Accordingly, it will be appreciated that the above described example embodiments should not be construed to narrow the scope or spirit of the invention in any way more restrictive than as defined by the specification and appended claims. It will be appreciated that the scope of the invention encompasses many potential embodiments, some of which will be further described below, in addition to those here summarized.

### BRIEF DESCRIPTION OF THE DRAWING(S)

Having thus described embodiments of the invention in general terms, reference will now be made to the accompanying drawings, which are not necessarily drawn to scale, and wherein:

FIG. 1 illustrates a cross-sectional view of an example solar cell that may benefit from embodiments of the interconnect apparatus in accordance with the present invention;

FIG. 2 illustrates a flowchart according to an example method for manufacturing an example solar cell that may benefit from embodiments of the interconnect apparatus in accordance with the present invention;

FIG. 3 illustrates a plan view of an example solar cell comprising a solderable interconnect apparatus in accordance with an example embodiment of the present invention;

FIG. 4 illustrates a flowchart according to an example method for manufacturing a solderable interconnect apparatus in accordance with an example embodiment of the present invention;

FIG. 5 illustrates a flowchart according to an example method for manufacturing a solderable interconnect apparatus in accordance with an example embodiment of the present invention; and

FIG. 6 illustrates an example solar module with four solar cells comprising interconnect apparatus in accordance with an example embodiment of the present invention.

FIG. 7 illustrates a cross-sectional view of an example embodiment of an interconnect apparatus on a solar cell with connected interconnect ribbon.

### DETAILED DESCRIPTION

As used herein, embodiments in which a first element is described to be “overlying,” “over,” or “above” a second element may generally be taken to signify that the first element is closer to the primary illuminated surface or primary illumination source. For example, if a first element is said to be overlying a second element, the first element may be closer to the sun. Similarly, embodiments in which a first element is described to be “underlying,” “under,” and “below” a second element may generally be taken to signify that the first element is further from the primary illuminated surface or primary illumination source. For example, if a first element is said to be underlying a second element, the first element may be further from the sun.

It should be noted that, in various embodiments, forms of secondary illumination, such as light returning to the device from a reflective surface located behind or beyond the device after the light originating from a primary illumination source has passed through or around the device, may be considered separate from the primary illumination source.

Some embodiments of the present invention will now be described more fully hereinafter with reference to the accompanying drawings, in which some, but not all embodiments of the invention are shown. Those skilled in this art will understand that the invention may be embodied in many different forms and should not be construed as limited to the embodiments set forth herein; rather, these embodiments are provided so that this disclosure will satisfy applicable legal requirements. Like reference numerals refer to like elements throughout.

Some common contact materials used in solar cells, particularly with respect to rear contacts, may comprise non-solderable materials, such as aluminum. Alloying aluminum together with an underlying silicon substrate to form a rear contact may result in either a high-low junction back surface field in p-type solar cells or a rear emitter in n-type solar cells. Many manufacturers utilize aluminum to form rear contacts due to its reflectivity, self-doping capabilities, stability, safety, and relatively low cost, among other considerations. As noted above, aluminum is not solderable, which often requires the addition of solderable connections to enable interconnection of solar cells. Furthermore, aluminum back contacts are comprised of small aluminum particles (about 2 to 20 μm in size) bound rather weakly to each other by sintering during the alloying process. The weak bonds generally contribute to a low cohesion aluminum back contact. Therefore, forces which put the aluminum layer in tension vertically may lead to separation within the aluminum layer.

In p-type solar cells, a solution for providing solderable connections to aluminum back contacts is to screen print one or more silver, or silver-aluminum, soldering pads directly onto the back surface of the silicon substrate prior to applying the aluminum contact. The soldering pads typically measure about 10 μm thick and 4 mm wide by 154 mm long when applied to a 156 mm pseudosquare solar cell. Once the silver soldering pads are applied directly to the silicon substrate, the aluminum paste is then screen printed to cover the remainder of the surface of the substrate and slightly overlap the silver soldering pads. As a result, the aluminum-doped back surface field is not formed underneath the silver soldering pads, and the aluminum back contact is segmented into multiple regions. The lack of an aluminum-doped back surface field under the soldering pads may result in a loss of efficiency of about 0.2% absolute for single crystal silicon solar cells. Furthermore, the silver, or silver-aluminum, material is relatively expensive. The silver material required for a 156 mm pseudosquare solar cell with three silver soldering pads as described above may cost about $0.20 per solar cell as of December 2010.

There is presently no viable solution for forming solderable connections to n-type solar cells having an aluminum back contact. In some n-type solar cells, the p-n junction is formed at the interface of the aluminum-doped emitter, which is formed from the aluminum back contact material during a heat treatment, and the silicon substrate. Therefore, the solution described above with respect to p-type solar cells may not be used with n-type solar cells. That is, if silver soldering pads were formed directly on the silicon substrate, the soldering pads would shunt the p-n junction. Similarly, attempts to form contacts, such as copper contacts, directly on the aluminum back contact could potentially lead to the copper diffusing through the aluminum back contact and poisoning the silicon, which could also lead to shunting the p-n junction. This is especially true if the contact system is heated to an appreciably elevated temperature. Additionally, even if forming a solderable contact on the aluminum back contact, the cell may experience poor adhesion between the solderable contact and the aluminum layer. Accordingly, no cost-effective and production-worthy method for interconnecting n-type solar cells with a full back aluminum contact currently exists, thereby inhibiting the potential of relatively high-efficiency (e.g. greater than 18% efficiency) rear junction solar cells.

The inventors have discovered a new approach to producing an interconnect apparatus that solves a number of the problems described above. In particular, an interconnect apparatus, as well as methods for manufacturing such an interconnect apparatus, comprising a copper layer and soldering layer formed over a high-cohesion aluminum back contact is described herein.

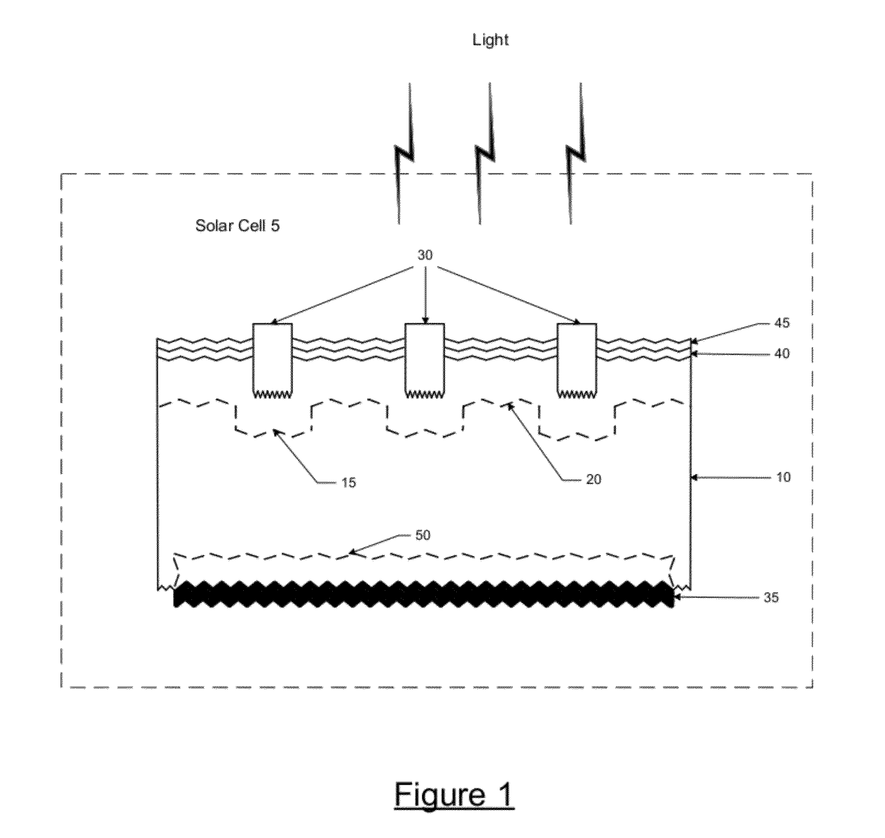

FIG. 1 illustrates an example embodiment of a solar cell 5 that may benefit from embodiments of the interconnect apparatus in accordance with the present invention. As will be described in further detail below, the substrate of the finished solar cell 5 may comprise three main semiconductor regions, namely a base layer 10, a front surface layer 15, 20, and a back surface layer 50. In various embodiments, the front surface layer 15, 20 and the back surface layer 50 may be more heavily doped than the base layer 10. The front surface layer 15, 20 and the back surface layer 50 may have opposite conductivity types. For example, in embodiments where the front surface layer 15, 20 is doped to be n-type, the back surface layer 50 may be doped to be p-type. The base layer 10, in these embodiments, may comprise the portion of the original substrate which has not been further doped (i.e. to form the front and back surface layers) during the process of manufacturing the solar cell 5.

The solar cell 5 may be formed of a semiconductor substrate. The substrate may be composed of silicon (Si), germanium (Ge) or silicon-germanium (SiGe) or other semiconductive material, or it may be a combination of such materials. In the case of monocrystalline substrates, the semiconductor substrate may be grown from a melt using Float Zone (FZ) or Czochralski (Cz) techniques. The resulting mono-crystalline boule may then be sawn into wafers to form the substrates. In other embodiments, the substrate can be multi-crystalline, which may be less expensive than monocrystalline substrates.

The front and back surfaces of the substrate may define pyramidal structures created by their treatment with a solution of potassium hydroxide (KOH) and isopropyl alcohol (IPA) during an anisotropic etching process. The presence of these structures increases the amount of light entering the solar cell 5 by reducing the amount of light that is lost by reflection from the front surface. The pyramidal structures on the back surface may be fully or partially destroyed during formation of a back contact by alloying aluminum with silicon.

According to the example solar cell 5 embodiment of FIG. 1, the substrate may be doped with impurities of a first conductivity type to create a base layer 10. If the substrate is composed of silicon (Si), germanium (Ge) or silicon-germanium (Si—Ge), the base layer 10 may be doped with boron (B), gallium (Ga), indium (In), aluminum (Al), or possibly another element to induce p-type conductivity, thereby forming a p-type base layer 10. In other embodiments, the substrate may be doped with phosphorus (P), antimony (Sb), arsenic (As) or another element to induce n-type conductivity, thereby forming an n-type base layer 10. N-type substrates are generally immune to light induced degradation (LID), which may lead to a loss of efficiency ranging from 0.2 to 0.5% absolute or 1.2 to 2.9% relative in p-type substrates, when exposed to a light source.

In some embodiments, a front surface layer may be formed by introducing dopant into the front surface of the substrate, for example by diffusion, ion implantation, or the like. The dopant may be of an n-type conductivity or p-type conductivity. In embodiments where the conductivity type of the front surface layer is the same as the base layer, the front surface layer may act as a front surface field layer. In other embodiments where the conductivity type of the front surface layer is opposite the conductivity type of the base layer, the front surface layer may act as an emitter layer. According to certain embodiments, the front surface layer may either be a substantially uniform layer or a selective front surface layer. A selective front surface layer may be made up of heavily doped selective regions 15 and lightly doped field regions 20. According to embodiments where the front surface layer comprises a selective emitter, a p-n junction may be formed at the interface between the base layer 10 and the doped regions 15, 20.

According to the example embodiment of FIG. 1, the front surface of the doped regions 15, 20 of the front surface layer and back surface of the base layer 10 represent a discontinuity in their crystalline structures, and dangling chemical bonds are present at these exposed surfaces. To prevent the dangling bonds from annihilating charge carriers, in some embodiments, one or more passivating layers may be formed on these surfaces.

In example embodiments, a front passivation layer 40 may contact the front surface of the doped regions 15, 20 of the front surface layer and, optionally, a passivation layer (not shown) may be formed along the sides and on the back surface of the exposed base layer 10. The passivation layers may comprise a dielectric material such as silicon dioxide (SiO₂) for a silicon substrate, or an oxide of another semiconductor type, depending upon the composition of the substrate. The passivation layers may have thicknesses in a range from 5 to 150 nanometers. Additionally, in certain embodiments, the front passivation layer 40 formed on the front surface layer and the optional passivation layer formed on the sides and back surface of the exposed base layer 10 may advantageously produce a high-quality, dielectric-passivated surface, for example when capped with a silicon nitride layer.

According to example embodiments, an antireflection layer 45 may be formed on the front passivation layer 40 on the front surface of the doped regions 15, 20 of the front surface layer. The antireflection layer 45 may be composed of silicon nitride (SiNₓ), aluminum oxide (Al₂O₃), titanium oxide (TiO₂), magnesium fluoride (Mg₂F), zinc oxide (ZnO), zinc sulfide (ZnS₂), or the like, or combinations of these materials. The antireflection layer 45 may have a thickness from 10 to 100 nanometers.

In a typical solar cell, the front contacts 30 may be formed of conductive materials such as silver (Ag). Generally, for silicon and other substrates, silver may be used to form front contacts on a surface of the substrate when the front surface layer is doped n-type. To decrease recombination where the metal directly contacts silicon and limit the proportion of metal covering the surface of the substrate, the front contacts 30 may be configured as point or line contacts (sometimes called “local contacts”).

The front contacts 30 may be formed by screen-printing the silver on the front surface of the antireflection layer 45. The front contacts 30 may further comprise solderable pads or bus bars to facilitate electrical connections to the front surface of the solar cell 5. According to example embodiments, the pattern of the front solderable pads or bus bars may be aligned with the pattern of the back contacts 35 described below.

In addition, for the front contacts 30, silver may be selected because of its high electrical conductivity to limit shadowing effects that can lower solar cell efficiency. In embodiments comprising a selective front surface layer, the front contacts 30 may be aligned with the heavily doped regions 15 of the selective front surface layer. In accordance with certain embodiments, the front passivation layer 40 and the antireflection layer 45 may be disposed on the front surface of the doped regions 15, 20 of the selective front surface layer prior to forming the front contacts 30. In this case, the front contacts 30 may physically penetrate the front passivation layer 40 and the antireflection layer 45 to make contact with the underlying regions of the selective front surface layer.

According to certain embodiments, the back contact 35 may be formed on the back surface of the substrate using screen-printed pastes. The paste used to form the back contact 35 may be an aluminum paste, for example an aluminum paste chosen to have high cohesion after firing. In some embodiments, the screen-printed paste may be applied to cover nearly the entire back surface of the substrate, for example the paste may not be printed over a narrow border near the edges of the wafer approximately 1 mm wide. In accordance with certain embodiments, firing of the screen-printed paste may form the back contact 35 and back surface layer 50. In some embodiments, the back contact 35 may physically penetrate an optional rear passivation layer during firing. In other embodiments, local back contacts may be formed through one or more holes or vias through a rear passivation layer, and the remainder of the back contact 35 may not penetrate or consume the rear passivation layer, for example when the paste used to form the back contact 35 is fritless.

As noted above, due to the firing of the back contact 35, a back surface layer 50, such as an aluminum-doped p⁺ silicon layer, may be formed by liquid phase epitaxial regrowth in the region between the base layer 10 and the back contact 35. In these embodiments, the back contact 35 may make electrical contact with the back surface layer 50. The back contact 35 may be composed at least partially of an aluminum-silicon eutectic composition. In embodiments where the conductivity type of the back surface layer 50 is opposite the conductivity type of the base layer 10, for example where the base layer is doped to be n-type and where the back surface layer 50 comprises a sufficient amount of aluminum to be doped p-type, a p-n junction may be formed at the interface between the base layer 10 and the back surface layer 50. According to these embodiments, the back surface layer 50, such as the aluminum-doped p⁺ silicon layer, may act as an emitter layer. Furthermore, the method may reduce the possibility of the back contact 35 shunting the p-n junction because the aluminum of the back contact 35 is the source of the p-type dopant for forming the back surface layer 50, which in turn forms the p-n junction at the interface of the base layer 10 and the back surface layer 50.

The back contact 35 may also serve as a reflective back layer for the solar cell 5. Having a reflective back layer provides a reflective surface to return incident light reaching the back to the substrate where it can generate free charge carriers. The thickness of the back contact 35 may be from 5 to 50 micrometers in thickness. The back layer may, in some embodiments, provide a measure of reflectivity.

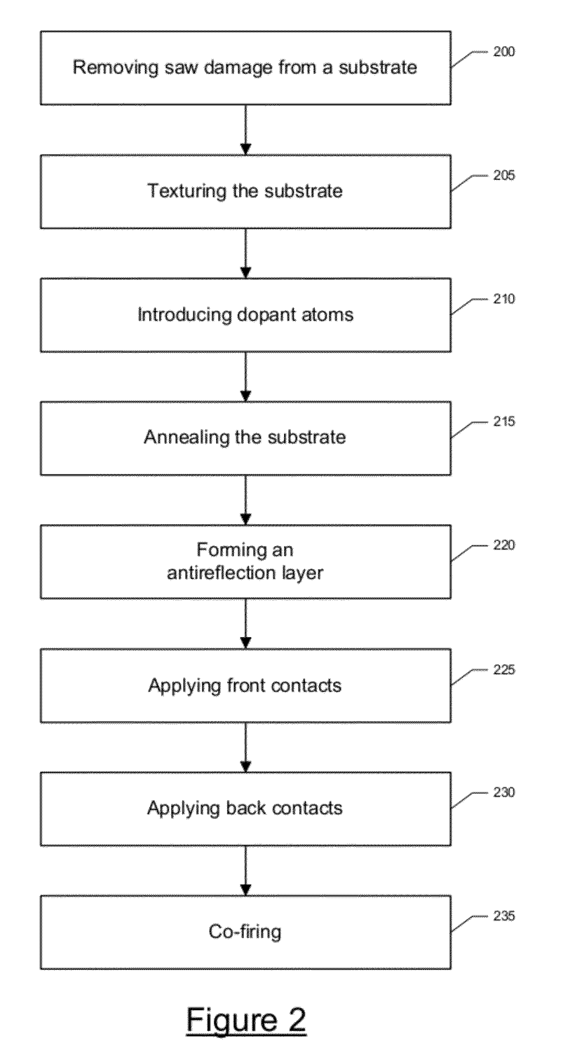

FIG. 2 illustrates a flowchart according to an example method for manufacturing an example embodiment of a solar cell 5 that may benefit from embodiments of the interconnect apparatus in accordance with the present invention. Referring to FIG. 2 at operation 200 a substrate is provided. The substrate may be as described above with respect to FIG. 1. According to various embodiments, the substrate may be doped with n-type dopant to form an n-type base layer 10. In other embodiments, the substrate may be doped with p-type dopant to form a p-type base layer 10. The dopant concentration may be in a range from 10¹³ to 10¹⁷ atoms per cubic centimeter (atoms/cm³). The thickness of the substrate may be in a range from 50 to 500 μm. Resistivity of the substrate may be in a range from 0.1 to 300 Ohm-cm. Monocrystalline or multicrystalline, or possibly string ribbon, thin silicon film or other types of substrates, may be used.

At operation 200, saw damage may be removed from the surface of the substrate to prepare it for processing. The removal of saw damage may be accomplished by immersion of the substrate in a bath of potassium hydroxide (KOH) having, for example, about a 1-10% concentration, at a temperature from about 60 to 90° Celsius to etch away saw damage on the surfaces of the substrate.

At operation 205, the substrate may be textured. For example, the substrate may be textured by anisotropically etching it by immersion in a bath of potassium hydroxide and isopropyl alcohol (KOH-IPA). The KOH-IPA etches the surfaces of the substrate to form pyramidal structures with faces at the <111> crystallographic orientation. The resulting pyramidal structures help to reduce reflectivity at the front surface and to trap light within the substrate where it can be absorbed for conversion to electric energy.

At operation 210, in some embodiments, dopant atoms may be introduced to the front surface of the substrate to form the doped layers of the front surface layer 15, 20. According to various embodiments, the dopant atoms may be introduced by diffusion, ion implantation, or the like. The dopant atoms may have the same conductivity as the base layer 10, or the dopant atoms may have the opposite conductivity from the base layer 10. In certain embodiments where the dopant is n-type, the dopant may be phosphorus ions introduced by implantation, for example P³¹⁺, or the like. In embodiments where the dopant is p-type, the dopant may be boron ions, for example. In some embodiments, the selective front surface layer may be formed by diffusion or by a hybrid diffusion and ion implantation process.

At operation 215, the doped substrate may be subjected to a heating step to form a selective front surface layer. According to some embodiments, the substrate may be introduced into a furnace for annealing, for example an automated quartz tube furnace. In embodiments where ion implantation is performed, operation 215 may comprise an annealing operation, which may be used to accomplish several objectives at once. First, the annealing operation 215 may activate the implanted dopant ions, that is, the heat energy of the anneal operation creates vacancies in the silicon lattice for the dopant ions to fill. Second, the annealing may drive the dopant ions deeper, for example to a desired depth, into the substrate. Third, the annealing operation 215 may repair damage to the crystalline lattice of the substrate caused by ion implantation. Fourth, the annealing operation 215 may be used to grow a passivating layer 40 on the front surface of the doped regions of the selective front surface layer 15, 20 and optionally on the sides and back surface of the exposed base layer 10.

According to example embodiments, the annealing operation 215 may begin by loading the substrates into a furnace at an initial temperature. Once the substrates are loaded into the furnace, the temperature may be ramped up over a first period of time. This temperature may then be maintained for a second period of time. During this second period of time, while the temperature is being maintained, oxygen may be introduced to the furnace. The introduction of oxygen may occur for all or a portion of the second period of time. The introduced oxygen may grow an in situ passivating oxide layer 40 on the front surface of the doped regions 15, 20 of the selective front surface layer and optionally on the sides and back surface of the exposed base layer 10. Finally, the temperature may be ramped down to a final temperature prior to unloading the substrates.

At operation 220, an antireflection layer 45 may be formed on the front passivating layer 40. The antireflection layer 45 may be formed by plasma enhanced chemical vapor deposition (PECVD). Some alternatives to the PECVD process may include low pressure chemical vapor deposition (LPCVD), sputtering, and the like. The antireflection layer 45 may have a thickness from 50 to 90 nanometers and an index of refraction of about 2.0.

At operation 225, the material for the front contacts 30 of the solar cell 5 may be applied to the front surface of the antireflection layer 45. According to various embodiments, the front contacts 30 may be screen-printed using a screen printer with optical alignment. The front contacts 30 may be applied using, in certain embodiments, a silver paste. The configuration and spacing of the front contacts 30 may be defined by the contact pattern of the screen. In certain embodiments, the front contacts 30 can be 50 to 150 micrometers in width and spaced apart by 1.0 to 2.5 millimeters. The paste for the front contacts 30 may be subsequently dried with a belt furnace.

In various example embodiments, the pattern of the screen, such as a grid pattern, line pattern, or the like, may be designed specifically for a selective front surface layer formed by embodiments of the method described above. For example, the pattern of the front contacts 30 may be designed so that they are aligned and printed within the selective regions 15 of the selective front surface layer. According to example embodiments, alignment of the front contacts 30 with the selective regions 15 of the selective front surface layer may be accomplished through a variety of techniques known to those of ordinary skill, including optical alignment using a reference edge or another fiducial mark formed on the solar cell 5 to indicate a position relative to which alignment is to be performed, butt-edge alignment against two posts, alignment by camera to the center or edge of the substrate, or the like.

At operation 230, the material for the back contact 35 may be applied to the back surface of the substrate. According to example embodiments, the material for the back contact 35 may be screen-printed on a back passivating layer on the back surface of the substrate. The material for the back contact 35, such as an aluminum paste, may be selected to exhibit high cohesion after firing. In certain embodiments, the paste may be screen-printed across nearly the entire back surface of the substrate. In these embodiments, the paste used to form the back contact 35 may not be printed over a narrow border near the edges of the wafer approximately 1 mm wide. In other embodiments, the paste used to form the back contacts 35 may be printed across only a portion of the back surface of the substrate.

At operation 235, the substrate with the front and back contacts 30, 35 applied may be heated or co-fired in a belt furnace, such as an in-line belt furnace or the like. In the process of co-firing the structure, according to example embodiments, the front contacts 30 may fire through the front passivating layer 40 and the antireflection layer 45 to form a physical connection with the doped regions 15, 20 of the selective front surface layer. In various embodiments, the front contacts 30 may only make physical connection with the selective regions 15 of the selective front surface layer. The firing temperature may be chosen such that the metal particles, such as silver, in the front contact paste form an ohmic contact with the selective front surface layer without migrating below the depth of the front surface layer.

During the co-firing at operation 235, aluminum from the paste used to form the back contact 35 may alloy with silicon from the substrate. In some embodiments, the temperature of the furnace may be high enough during the alloying so that the aluminum may effectively dissolve silicon. When the substrate cools following the co-firing, a back surface layer 50, such as an aluminum-doped p⁺ silicon layer, may be formed into the substrate by liquid phase epitaxial re-growth. According to certain embodiments where the base layer 10 is doped to have n-type conductivity and the back surface layer 50 is doped to have p-type conductivity, a p-n junction may be formed at the interface of the base layer 10 and the back surface layer 50 to create a back junction solar cell 5. In other embodiments where the base layer 10 is doped to have p-type conductivity, a high-low junction, or back surface field, may be formed at the interface of the base layer 10 and the back surface layer 50. The remainder of the aluminum back contact 35 may comprise an aluminum-silicon eutectic metal layer. In certain embodiments, a portion of the back contact 35 near the back of the solar cell 5 may comprise mostly aluminum. The material of the back contact 35 may form a physical and electrical connection with the back surface layer 50.

The various embodiments of a solar cell 5, and methods for its manufacture, as described above with respect to FIGS. 1 and 2, may benefit from various embodiments of a solderable interconnect apparatus, and methods for its manufacture, in accordance with the present invention.

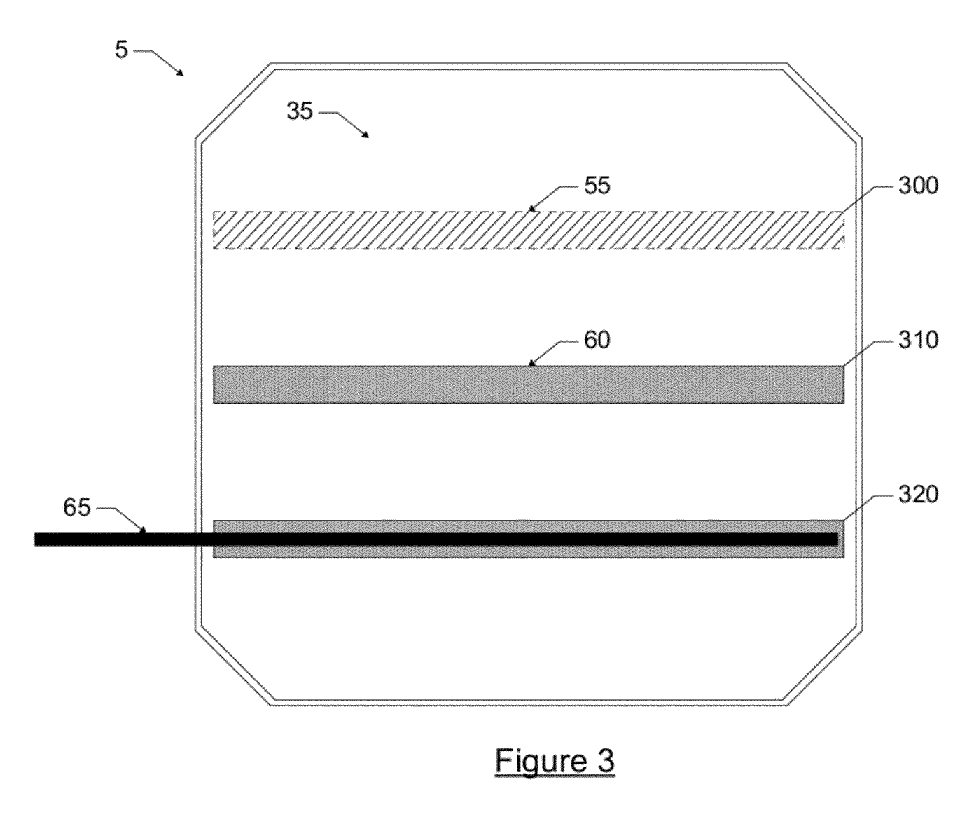

FIG. 3 illustrates various stages in the formation of an interconnect apparatus, according to example embodiments of the present invention, formed on an example solar cell device, such as the example solar cell described with respect to FIGS. 1 and 2. It should be understood that the various stages depicted in FIG. 3 are merely illustrative of one method for forming an interconnect apparatus according to an example embodiment and, therefore, should not be taken to limit the scope of the disclosure.

According to example embodiments where a solar cell comprises an interconnect apparatus, the metal paste used to form the back contact 35 of the solar cell 5 may be selected to provide a high-cohesion aluminum layer after alloying. Apart from aluminum, in other embodiments, the interconnect apparatus may be formed over the surface of any type of conductive material.

According to various embodiments, the interconnect apparatus may comprise a metal layer 55 formed on a conductive surface, for example the aluminum back contact 35 of the example solar cell 5. The metal layer 55 may comprise any type of solderable metal. For example, the metal layer 55 may comprise copper, nickel, silver, a tin/silver mixture, or the like. In some embodiments, the metal layer 55 may comprise one or more soldering pads. FIG. 3 illustrates an example metal layer 55 comprising a soldering pad formed over the back contact of a solar cell 5 at 300. According to other embodiments, the metal layer 55 may comprise one or more sputtered metal layers covering one or more portions or nearly the entire back surface of the back contact 35.

According to embodiments where the metal layer 55 comprises one or more soldering pads, the soldering pads may be plasma deposited soldering pads. In some embodiments, the metal layer 55 may comprise three soldering pads. Each soldering pad may be approximately 0.1 to 15 μm thick, for example 5 μm thick, and nominally 4 mm wide by 150 mm long. The thickness of each soldering pad, in some instances, may not be uniform but rather may vary somewhat in thickness along its length. In other embodiments, the soldering pads may be of a length one to three millimeters less than the length of the underlying conductive surface. According to example embodiments, the soldering pads may be aligned with the front solderable pads or bus bars.

According to various embodiments, the one or more sputtered layers of the metal layer 55 may be at least 0.1 μm thick. In some embodiments, the metal layer 55 may be from 0.1 to 15 μm thick, for example 1 μm thick. In some embodiments, the sputtered layer may cover nearly the entire conductive surface, for example the entire back contact 35 of the example solar cell embodiment of FIG. 1, except for a border approximately 3 mm wide at the edge of the conductive surface. In other embodiments, the sputtered layers may be deposited as stripes to form one or more solderable pads, for example by employing masking during the sputtering process.

In certain embodiments, the solar cell 5 may have local back contacts 35 to the underlying silicon substrate. For example, aluminum dot or line contacts may be made to the silicon substrate through a passivation layer on the back surface of the base layer 10. According to example embodiments, a full aluminum back contact 35 may cover the entire surface of the passivation layer and contact the silicon substrate through one or more local holes or vias. In these embodiments, the interconnect apparatus may be formed on the aluminum back contact 35 as described above. According to other embodiments, local aluminum back contacts 35 may be made through the one or more holes or vias, but the remainder of the back surface of the substrate may not be covered with a full aluminum back contact. In these embodiments, the metal layer 55 may cover nearly the entire back surface of the substrate, thereby connecting all of the local back contacts 35.

In example embodiments, the interconnect apparatus may further comprise a solder layer 60, formed on the metal layer 55. The solder layer 60 may comprise a tin/lead (Sn/Pb) solder, for example a sixty percent tin/forty percent lead solder (Sn60/Pb40). According to certain embodiments, the solder layer 60 may completely cover the metal layer 55. In this regard, the width of the solder layer 60 may be about the same as the metal layer 55, for example approximately 4 mm wide. The solder layer 60 may be approximately 70 to 100 μm thick, or in some instances greater than 100 μm. In some embodiments, the thickness of the solder layer 60 may depend at least partially on the width of the solder layer 60 and/or metal layer 55. For example, as the width of the metal layer 55 decreases, the thickness of the solder layer 60 may also decrease. FIG. 3 illustrates an example solder layer 60 formed over a metal layer 55 on the back contact of a solar cell 5 at 310.

One or more solar cells may be interconnected via various embodiments of the interconnect apparatus and an interconnect ribbon 65, or the like. In example embodiments, the interconnect ribbon 65 may be about 1.5 mm wide by 0.15 mm thick. The interconnect ribbon 65 may comprise a conductive metal ribbon. For example, the interconnect ribbon 65 may comprise a copper metal ribbon. In some embodiments, the metal ribbon may be coated with a solder material. For example, the metal ribbon may comprise a solder coating that may be about 20 μm thick. In this regard, the interconnect ribbon 65 may be connected to a solderable surface by placing the interconnect ribbon 65 in contact with the solderable surface, applying sufficient heat to temporarily melt the solder coating, and removing the heat to allow the solder coating to cool, thereby forming a bond with the solderable surface. FIG. 3 illustrates an example interconnect ribbon 65 soldered to a solder layer 60 formed over a metal layer 55 on the back contact of a solar cell 5 at 320.

According to example embodiments, an interconnect ribbon 65 may be soldered to the metal layer 55 or the solder layer 60 of the interconnect apparatus. For example, the interconnect ribbon may be used to electrically connect two or more solar cells. The combination of the interconnect ribbon 65, the layers of the interconnect apparatus (e.g. including the copper layer 55 and solder layer 60), and the conductive surface of a particular solar cell may be considered an interconnect stack. In various embodiments, the interconnect ribbon 65 may be significantly narrower than the solderable surface to which it is connected (e.g. the metal layer 55 or the solder layer 60). For example, the interconnect ribbon 65 may be 1.5 mm wide, and the interconnect ribbon 65 may be soldered to, for example, a metal layer 55 or solder layer 60 that may be 4 mm wide. In these embodiments, the solder layer 60 may significantly improve the adhesive strength of the interconnect stack. For example, the additional thickness and/or width of the solder layer may increase the durability and reliability of the interconnect stack.

Without the solder layer 60, the interconnect stack may have a very low pull strength, even in embodiments where a high cohesion aluminum layer is formed. For example, the narrow interconnect ribbon 65 may exhibit low to non-existent pull strength when applied directly to the metal layer 55. In this regard, when pulling on the soldered interconnect ribbon 65, the metal layer 55 may be pulled from the conductive contact, in some instances further removing a portion of the conductive contact. In embodiments of the present invention comprising a solder layer 60, however, the interconnect stack may be capable of withstanding a high pull force applied to the interconnect ribbon. According to these example embodiments, the interconnect ribbon may be capable of withstanding a pull force of about 50 to 500 grams-force per millimeter of ribbon width, such as 100 grams-force per millimeter, applied to the unsoldered end of the interconnect ribbon at a pulling angle of about 180° toward the soldered end of the interconnect ribbon.

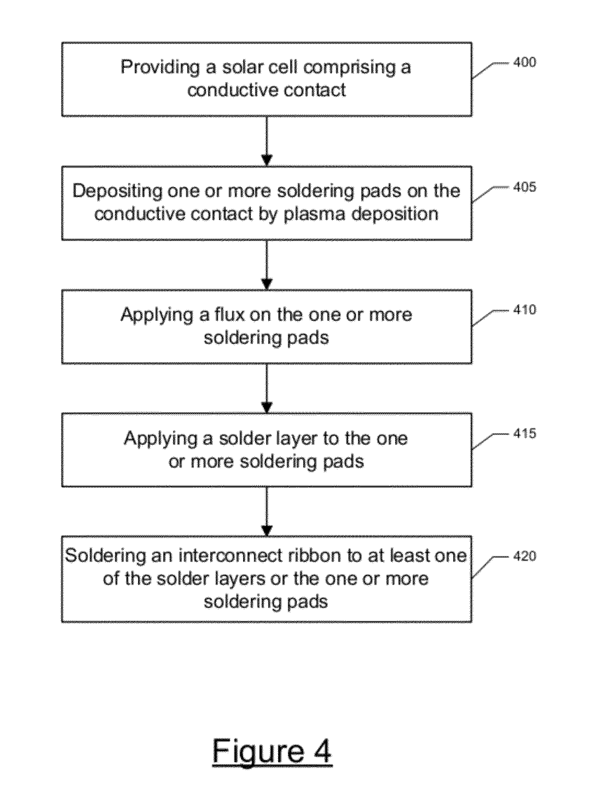

FIG. 4 illustrates a flowchart according to an example method for manufacturing a solderable interconnect apparatus in accordance with an example embodiment of the present invention. FIG. 4 thus discloses the methods for its manufacture in accordance with the present invention.

Referring to FIG. 4 at operation 400 a solar cell comprising a conductive contact, for example a metal (e.g. aluminum) contact, may be provided. The solar cell may be any solar cell having a conductive contact, for example, a solar cell as described above with respect to FIGS. 1 and 2. According to some embodiments, one or more of the conductive contacts of the solar cell may comprise a metal to which a solderable connection is difficult to make, such as aluminum. The material used to form the aluminum contact of the solar cell may be selected to provide high cohesion in the aluminum contact layer.

At operation 405, one or more soldering pads may be deposited on the conductive contact of the solar cell. For example, three soldering pads measuring about 5 μm thick and 4 mm wide by 150 mm long may be deposited on an aluminum contact of a solar cell. In other embodiments, each soldering pad may be segmented into sections along the length of the pad, for example each soldering pad may be divided into eight segments measuring 4 mm wide and 10 mm long with a 10 mm gap between adjacent segments. In embodiments where the soldering pads are formed on the back contact of a solar cell, the soldering pads may be aligned with the front bus bars of the solar cell. According to example embodiments, the soldering pads may be deposited by plasma deposition using nanoparticles, for example copper nanoparticles. An example method for performing plasma deposition may involve the use of the Plasmadust equipment manufactured by Reinhausen Plasma. In some embodiments, plasma deposition may occur at a rate acceptable for mass production, for example a rate of about 2,400 cells per hour.

At operation 410, a flux optionally may be applied to the surface of the one or more soldering pads. The flux may facilitate the soldering of the metal layer 55 with the solder layer 60 at operation 415. In example embodiments, the flux may be a low residue flux. The flux may, in some embodiments, be a part of the solder applied to form the solder layer 60.

At operation 415, a solder layer 60 may be applied to the surface of the one or more soldering pads. In embodiments where a flux layer is applied to the surface of the one or more soldering pads, the solder layer 60 may be melted onto the fluxed surface of the one or more soldering pads. According to certain embodiments, the solder layer 60 may comprise any common tin/lead solder such as Sn60/Pb40, or the like. The solder layer 60 may be applied by any number of methods known in the art, for example, via a soldering iron, syringe, solder pre-forms, wave soldering process, plasma process, or the like. The temperature required to melt the solder of the solder layer 60 may be sufficiently low to prevent degradation of the solar cell. For example, the melting point of Sn60/Pb40 solder is only about 188° C.

At operation 420, an interconnect ribbon 65, or the like, may be connected to at least one of the metal layer 55 or the solder layer 60. For example, the interconnect ribbon may be connected to a solder layer 60 formed on a soldering pad. According to various embodiments, the interconnect ribbon 65 may be soldered along the length of the metal layer 55 or the solder layer 60. In some embodiments, a portion of the interconnect ribbon 65 may extend beyond the solar cell. In some instances, the extended portion of the interconnect ribbon 65 may be soldered to a front bus bar of a neighboring solar cell to electrically connect the solar cells. In other instances, the extended portion of the interconnect ribbon 65 may be soldered to one or more string-to-string bus bars 67 to allow for connecting neighboring strings of solar cells.

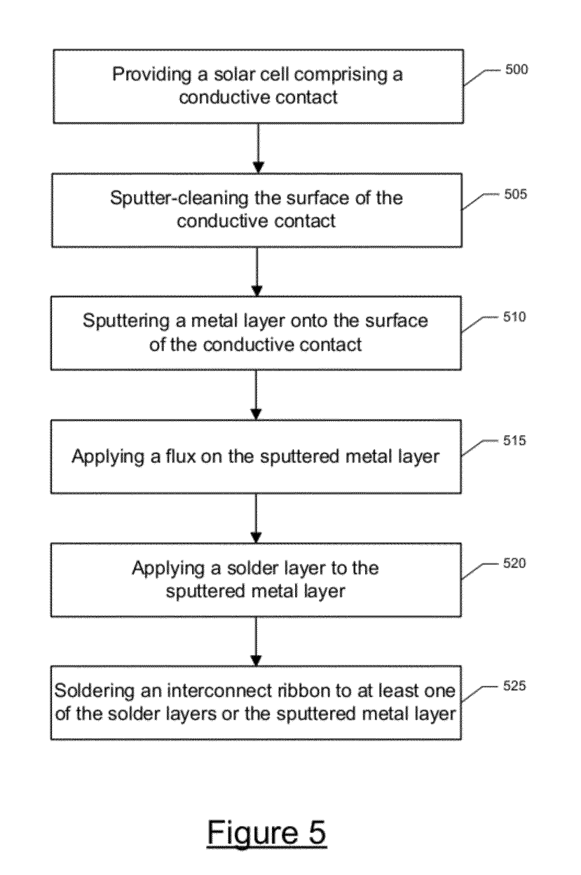

FIG. 5 illustrates a flowchart according to another method for manufacturing a solderable interconnect apparatus in accordance with an example embodiment of the present invention.

Operation 500 is identical to operation 400 as described above with respect to FIG. 4. At operation 505, the surface of the conductive contact of the solar cell may undergo a sputter cleaning The sputter cleaning may prepare the surface for sputtering a metal layer 55 onto the conductive contact. For example, the sputter cleaning may remove oxidation and/or adsorbed molecules or layers, such as oxygen, carbon dioxide, water vapor, or the like.

At operation 510, a metal layer 55 may be sputtered onto the surface of the conductive contact, such as an aluminum back contact. According to example embodiments, the metal layer 55 may be sputtered from a pure metal target, for example a copper target. Any number of sputtering techniques may be used to sputter the metal layer 55, such as direct current (DC) sputtering, pulsed DC sputtering, or radio frequency (RF) sputtering. In some embodiments, the metal layer 55 may cover nearly the entire conductive surface except for a border about 3 mm wide along the edges of the conductive contact. The metal layer 55 may be sputtered at a thickness of about 0.1 to 15 μm thick, for example 1 μm thick.

The remaining operations 515 to 525 are nearly identical to operations 410 to 420 as described above with respect to FIG. 4. In example embodiments, the solder layer 60 and the optional flux layer may be applied to the sputtered metal layer 55 in one or more strips measuring about 4 mm wide by 150 mm long. That is, the solder layer 60 may not cover the entire surface of the sputtered metal layer 55. According to various embodiments, the one or more strips may be aligned with the front bus bars of the solar cell 5.

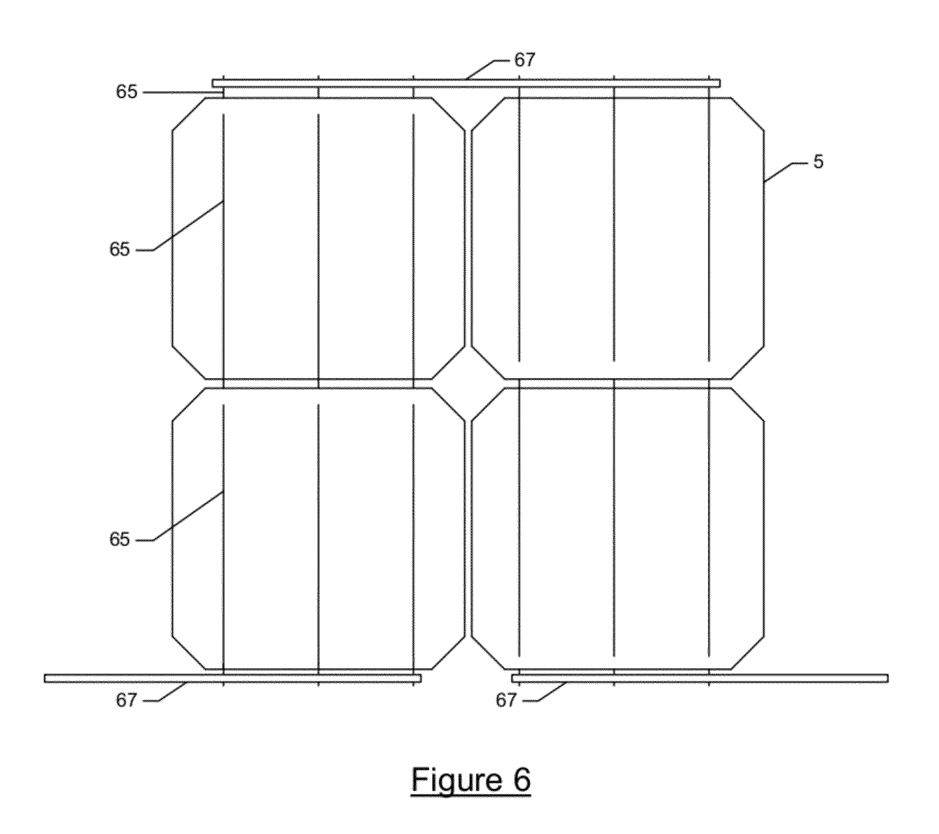

According to various embodiments, one or more solar cells, for example solar cells as described with respect to FIGS. 1 and 2, each comprising one or more interconnect apparatuses as described with respect to FIGS. 3, 4, and 5, may be interconnected to form a solar module. The front view of an example solar module comprising four interconnected solar cells with interconnect apparatuses is depicted in FIG. 6. However, various embodiments of the solar module may have anywhere from about two to about 120 solar cells, for example 60 or 72 solar cells. As shown in the example embodiment of FIG. 6, an interconnect ribbon 65 may connect the negative front terminal of a solar cell 5 to the positive rear terminal of an adjacent solar cell 5. At the end of a string of adjacent solar cells, an interconnect ribbon 65 may connect one terminal of a solar cell 5 to a string-to-string bus bar 67. The opposite terminal of the end solar cell 5 of a neighboring string of solar cells may also be connected to the string-to-string bus bar 67. In this regard, the string-to-string bus bar may electrically connect the end solar cells of one or more neighboring strings of solar cells.

In some embodiments, the solar module may comprise one or more solar cells comprising interconnect apparatuses according to various embodiments of the present invention; a cover glass, for example Solite 2000 AGC Glz; one or more ethylene vinyl acetate encapsulants, for example STR-Solar Photocap 15295 P/UF; a cell string comprising copper interconnect ribbon with solder coating, for example Ulbrich #7746-9992; and a backsheet, for example Madico Protekt HD (white). The lamination temperature and time may be selected to successfully perform the lamination process without significantly degrading the solar cells or significantly reducing the performance of the solar cells, for example due to shunting. For example, the lamination temperature may be about 150° Celsius, and the lamination time may be about 15 minutes. According to example embodiments, the one or more solar cells may be adjoined via soldered interconnect ribbons or wires to adjacent solar cells in the solar module and ultimately to a load to provide power thereto upon exposure of the solar module to light.

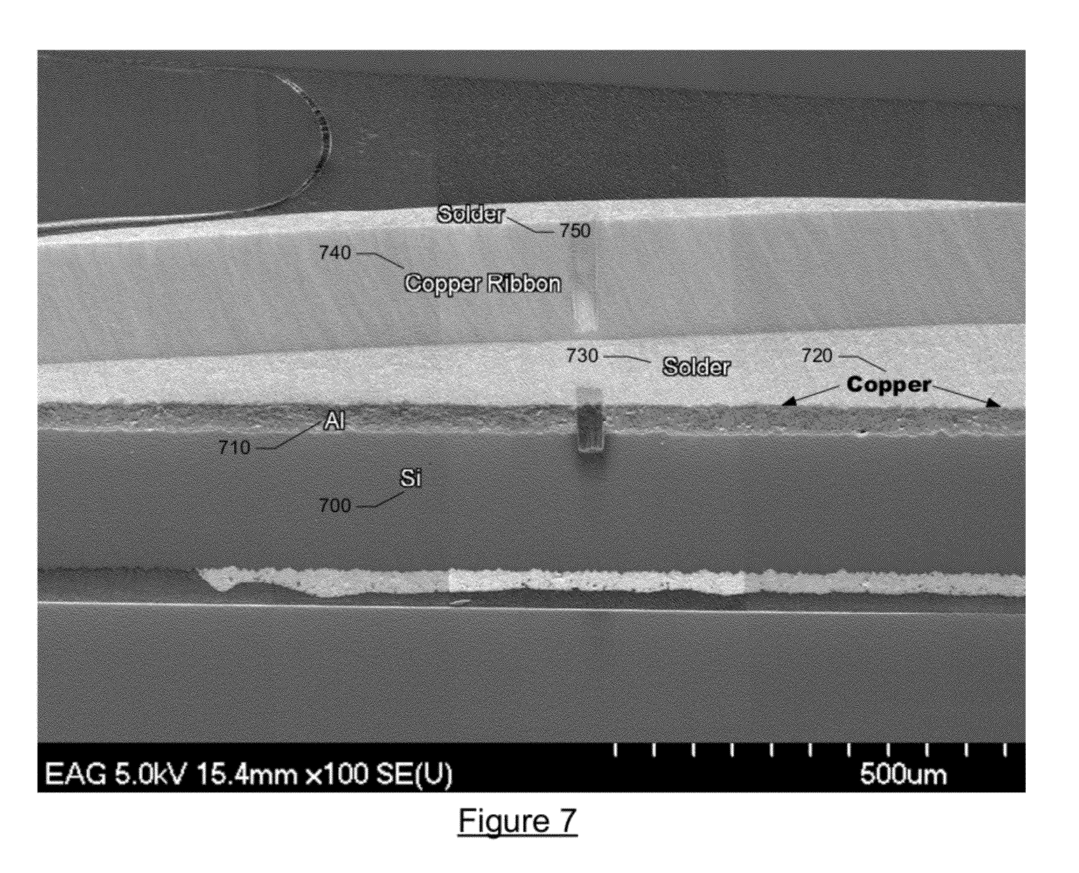

FIG. 7 provides a cross-sectional view of an example embodiment of an interconnect apparatus on a solar cell with connected interconnect ribbon. In this example embodiment, an aluminum back contact 710 is shown formed over a silicon substrate 700. The aluminum back contact 710 is about 25 microns thick in this example. This example embodiment also depicts the metal layer 55 as a copper soldering pad 720 formed on the aluminum back contact 710. In this example cross section, the copper soldering pad 720 is about 3 microns thick, making it barely visible in the figure. The copper soldering pad 720 in FIG. 7 is a shade of gray lighter than the aluminum back contact 710 and a shade of gray darker than the solder layer 730. The first solder layer 730 depicted in the example cross section comprises solder from the solder layer 60 formed on the metal layer 55 (i.e. the copper soldering pad 720), as described in various embodiments above, as well as solder from the solder coating of the interconnect ribbon 65 (i.e. copper interconnect ribbon 740). The first solder layer 730 of this example has a combined thickness of about 50 microns on the left side of the figure and about 100 microns on the right side of the figure. The example cross section of FIG. 7 further depicts copper interconnect ribbon 740 over the first solder layer 730. In this example embodiment, the copper ribbon is about 150 microns thick. Finally, FIG. 7 depicts a second solder layer 750 over the copper interconnect ribbon 740. The second solder layer 750 comprises solder from the solder coating of the interconnect ribbon 65 (i.e. copper interconnect ribbon 740). In this example embodiment, the second solder layer 750 ranges from about 1 to 20 μm in thickness.

According to various embodiments, and as described above, an interconnect apparatus may be formed. More particularly, an interconnect apparatus comprising a metal layer 55 and solder layer 60 may be formed to a solar cell having a full conductive (e.g. aluminum) back contact to allow the solar cell to be interconnected with adjacent solar cells, for example in a solar module. Many advantages may be realized by forming the interconnect apparatus as described herein. For example, according to various embodiments, the interconnect apparatus may be formed on the full back conductive contact of a p-type solar cell without segmenting the back contact. In some embodiments, by providing an unsegmented full back conductive contact, an unbroken aluminum-doped back surface layer may be formed underneath the entire conductive back contact. Additionally, according to example embodiments, the interconnect apparatus may be formed on the full back conductive contact of an n-type solar cell without shunting the rear p-n junction.

In some embodiments, the formation of the interconnect apparatus on the conductive back contact of a solar cell does not significantly degrade the solar cell quality or performance, due at least in part to the relatively low temperature steps required to deposit the metal layer 55 (i.e. less than about 100° C.), apply the solder layer 60 (i.e. about 188° C.), attach the interconnect ribbon 65 (i.e. about 188° C.), and laminate the solar module (i.e. about 150° C.). Moreover, according to certain embodiments, the solar cell with interconnect apparatus may exhibit high fill factors (e.g. exceeding 79%) and high efficiencies (e.g. exceeding 18%), and, in some instances, the fill factor may even improve after the metal layer 55 is formed. According to certain embodiments, since the formation of the interconnect apparatus does not significantly degrade the efficiency of the solar cell, the performance and the efficiency of the solar cell can be optimized independently prior to forming the interconnect apparatus. In certain embodiments, solar cells joined together by various embodiments of the interconnect apparatuses and encapsulated in a solar module may exhibit performance commensurate with, or in some instances exceeding the performance of, state-of-the-art solar modules.

According to various embodiments, the application of the solder layer 60 to the metal layer 55 of the interconnect apparatus may provide the unexpected advantage of improving the pull strength of the interconnect stack (i.e. conductive contact, metal layer 55, solder layer 60, and interconnect ribbon 65). Interconnect ribbons 65 connected to an interconnect apparatus, in some embodiments, may exceed a pull strength of 100 grams-force per millimeter of ribbon width with the pulling angle of the ribbon tab at 180° relative to the length of soldered interconnect ribbon 65.

Furthermore, according to example embodiments, the use of copper soldering pads with a solder layer as in various embodiments of the present invention may significantly reduce costs of production. For example, as of December 2010, in a typical solar cell having three solderable silver-aluminum soldering pads measuring 10 μm thick and 4 mm wide by 154 mm long, the material costs of the silver-aluminum paste material alone is $0.201 per solar cell. In contrast, for a solar cell comprising three similarly sized copper soldering pads according to various embodiments of the interconnect apparatus of the present invention, the cost of the copper material may be as low as $0.024 per solar cell. Even adding the additional costs related to the equipment, maintenance, energy, and labor required to form the copper soldering pads (i.e. about $0.023 per solar cell), the total end cost of the copper soldering pads is only $0.047 per cell, which is $0.154 less than the price of the silver-aluminum material alone required for the prior art methods. Furthermore, the approximate cost of the solder used to form the solder layer 60 is only another $0.021 per solar cell. In certain embodiments, this difference in price may be equivalent to a ten to fifteen percent, or more, reduction in total cost of a solar cell.

Many modifications and other embodiments of the inventions set forth herein will come to mind to one skilled in the art to which these inventions pertain having the benefit of the teachings presented in the foregoing descriptions and the associated drawings. Therefore, it is to be understood that the embodiments of the invention are not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by other embodiments without departing from the scope of the appended claims. In this regard, for example, different combinations of steps, elements, and/or materials than those explicitly described above are also contemplated as may be set forth in some of the appended claims. Accordingly, the specification and drawings are to be regarded in an illustrative rather than restrictive sense. Although specific terms are employed herein, they are used in a generic and descriptive sense only and not for purposes of limitation.

What is claimed is:

1. A method for forming a rear junction solar cell having a solderable connection, comprising:
fabricating an n-type base layer;
applying a contact layer to one side of the n-type base layer;
alloying the contact layer with at least a portion of the n-type base layer thereby forming:
a p-type emitter layer such that the n-type base layer overlies the p-type emitter layer;
a contact such that the p-type emitter layer overlies the contact; and
a p-n junction at the interface of the n-type base layer and the p-type emitter layer;
forming one or more solderable metal regions on the contact; and
applying a solder layer to the one or more solderable metal regions to form one or more soldered metal regions.

2. The method of claim 1, wherein the contact and the contact layer comprise aluminum, and wherein the one or more solderable metal regions comprise copper.

3. The method of claim 2, wherein the one or more solderable metal regions comprise one or more copper soldering pads, and wherein forming one or more copper soldering pads on the contact further comprises:
depositing the one or more copper soldering pads on the contact by plasma deposition.

4. The method of claim 1, wherein forming one or more solderable metal regions on the contact further comprises:
sputtering the one or more solderable metal regions onto the contact.

5. The method of claim 4 further comprising:
sputter-cleaning the contact prior to sputtering the one or more solderable metal regions onto the contact.

6. The method of claim 1, further comprising:
applying a flux to the one or more solderable metal regions prior to applying the solder layer to the one or more solderable metal regions.

7. The method of claim 1, wherein the solder layer comprises a solder comprising about sixty percent tin and about forty percent lead.

8. The method of claim 1, wherein applying the solder layer to the one or more solderable metal regions comprises applying the solder layer using at least one of a soldering iron, a syringe, a soldering pre-form, a wave soldering process, or a plasma deposition process.

9. The method of claim 1, further comprising:
soldering an interconnect ribbon to at least one of the solder layer or the one or more solderable metal regions.

10. A rear junction solar cell having a solderable connection, comprising:
a substrate comprising an n-type base layer;
a p-type emitter layer, wherein the n-type base layer overlies the p-type emitter layer;
a p-n junction at the interface of the n-type base layer and the p-type emitter layer;
a contact, wherein the p-type emitter layer overlies the contact;
one or more solderable metal regions formed on the contact; and
a solder layer formed on the one or more solderable metal regions thereby forming one or more soldered metal regions.

11. The solar cell of claim 10, wherein the contact comprises aluminum and the one or more solderable metal regions comprise copper.

12. The solar cell of claim 11, wherein the one or more solderable metal regions comprise one or more copper soldering pads.

13. The solar cell of claim 10, wherein the one or more solderable metal regions comprises a sputtered copper layer formed over the contact.

14. The solar cell of claim 10 further comprising:
an interconnect ribbon soldered to at least one of the solder layer or the one or more solderable metal regions.

15. The solar cell of claim 14, wherein the interconnect ribbon exhibits a pull strength exceeding one hundred grams-force per millimeter of interconnect ribbon width when an unsoldered end of the interconnect ribbon is pulled at an angle of about 180 degrees toward a soldered portion of the interconnect ribbon.

16. The solar cell of claim 10, wherein the solder layer comprises about sixty percent tin and about forty percent lead.

17. A method for forming a solderable connection to a conductive surface, comprising:
forming one or more solderable metal regions on the conductive surface; and
applying a solder layer to the one or more solderable metal regions to form one or more soldered metal regions.

18. An interconnect apparatus for forming a solderable connection to a conductive surface, comprising:
one or more solderable metal regions formed on the conductive surface; and
a solder layer formed on the one or more solderable metal regions thereby forming one or more soldered metal regions.

19. A solar cell having a solderable connection, comprising:
a back contact;
one or more solderable metal regions formed on the back contact; and
a solder layer formed on the one or more solderable metal regions thereby forming one or more soldered metal regions.

20. The solar cell of claim 19 further comprising:
a substrate comprising a p-type base layer;
an n-type emitter layer formed over the p-type base layer; and
a p-n junction at the interface of the p-type base layer and the n-type emitter layer;
wherein the back contact is formed on the back surface of the p-type base layer.

21. A method for forming a solar cell having a solderable connection, comprising:
fabricating a p-type base layer;
forming an n-type emitter layer overlying the p-type base layer thereby forming a p-n junction at the interface of the p-type base layer and the n-type emitter layer;
forming a contact on a surface of the p-type base layer opposite the n-type emitter layer;
forming one or more solderable metal regions on the contact; and
applying a solder layer to the one or more solderable metal regions thereby forming one or more soldered metal regions.
